(19) United States
(12) Patent Application Publication
(10) Pub. No.: US 2014/0076353 A1
(43) Pub. Date: Mar. 20, 2014

(54) PLASMA MEDIATED ASHING PROCESSES

(71) Applicant: Lam Research Corporation, Fremont, CA (US)

(72) Inventors: Ivan L. Berry, Amesbury, MA (US); Carlo Waldfried, Middleton, MA (US); Shijian Luo, South Hamilton, MA (US); Orlando Escorcia, Falls Church, VA (US)

(73) Assignee: Lam Research Corporation, Fremont, CA (US)

(21) Appl. No.: 14/082,282

(22) Filed: Nov. 18, 2013

Related U.S. Application Data
(62) Division of application No. 13/117,488, filed on May 27, 2011.
Application No. 13/117,488 is a continuation-in-part of application No. 12/844,193, filed on Jul. 27, 2010.
Application No. 12/844,193 is a continuation-in-part of application No. 12/275,394, filed on Nov. 21, 2008.

(51) Int. Cl. H01L 21/02

(52) U.S. Cl. CPC H01L 21/02101
USPC 134/1.1

(57) ABSTRACT

A plasma ashing process for removing photoresist, polymers and/or residues from a substrate, the process includes placing the substrate including the photoresist, polymers, and/or residues into a reaction chamber; generating a plasma from a gas mixture comprising oxygen gas (0₂) and/or an oxygen containing gas; suppressing and/or reducing fast diffusing species in the plasma by adding an atomic oxygen scavenging gas to the gas mixture; and exposing the substrate to the plasma to selectively remove the photoresist, polymers, and/or residues from the substrate, wherein the plasma is substantially free from fast diffusing species.

### CROSS REFERENCE TO RELATED APPLICATION

This application is a continuation-in-part of and claims benefit to U.S. Non-provisional patent application Ser. No. 12/844,193 filed Jul. 27, 2010 and U.S. Non-Provisional application Ser. No. 12/275,394 filed Nov. 21, 2008, both of which are fully incorporated herein by reference.

### BACKGROUND OF THE INVENTION

The present disclosure generally relates to plasma mediated ashing processes that provide effective removal of organic materials from a semiconductor substrate while enabling reduced substrate oxidation and/or erosion during processing, and more particularly, to plasma mediated ashing processes wherein the plasma is substantially free of fast diffusing species.

The integrated circuit manufacturing process can generally be divided into front end of line (FEOL) and back end of line (BEOL) processing. The FEOL processes are focused on fabrication of the different devices that make up the integrated circuit, whereas BEOL processes are generally focused on forming metal interconnects between the different devices of the integrated circuit. Examining the International Technology Roadmap for Semiconductors (ITRS) for FEOL processing reveals critical performance challenges faced by future devices in a number of key areas including plasma ashing. For example, the roadmap for plasma ashing projects target silicon loss for the 45 nanometer (nm) generation to being no greater than 0.4 angstroms per cleaning step and no greater than 0.3 angstroms for the 32 nm generation.

Typically, sensitive substrate materials such as silicon implanted with very shallow dopants, SiGe, high-k dielectrics, metal gates, and the like are exposed during the photoresist removal process and can become damaged during the photoresist removal process. The substrate damage may generally be in the form of substrate erosion (e.g., physical removal of a portion of the substrate caused by etching, sputtering, and the like, e.g., silicon loss), substrate oxidation, dopant bleaching/concentration changes, or combinations thereof. These changes are undesirable as they will change the electrical, chemical, and physical properties of the substrate. Moreover, small deviations in the patterned profiles formed in the underlayers can adversely impact device performance, yield, and reliability of the final integrated circuit. For example, in a source and drain implant application, a patterned photoresist layer is formed over the silicon substrate at the source and drain regions prior to carrying out a high dose implant. During the high dose implantation process, the photoresist is subjected to relatively high energy ions that induce cross-linking reactions in the photoresist at a depth approximately equal to or slightly greater than the range of the ions. This cross-linking reaction and the resultant loss of hydrogen create a hardened upper portion of the photoresist layer, commonly referred to as the crust. The physical and chemical properties of the crust vary depending on the implant conditions and are generally more resistant to plasma mediated ashing processes than the underlying non-crosslinked photoresist. Because of this, more aggressive plasma chemistries are needed to remove the resist. At the same time, however, extremely shallow junction depths call for very high selectivity in the resist removal process. Silicon loss or silicon oxidation from the source/drain regions must be avoided during the high-dose ion implantation strip. For example, excessive silicon loss can deleteriously alter electrical current saturation at a given applied voltage as well as result in parasitic leakage due to decreased junction depth detrimentally altering electrical functioning of the device. Current plasma mediated ashing processes are generally unsuitable for this type of application.

Traditional FEOL plasma mediated stripping processes are typically oxygen (O₂) based followed by a wet clean step. However, oxygen based plasma processes can result in significant amounts of substrate surface oxidation, typically on the order of about 10 angstroms or more. The plasma oxidation rate of silicon or silicon-germanium for example is determined by the diffusion rate of the oxidizing specie through the growing surface oxide. Since the diffusion time is proportional to the oxide thickness, and the oxide thickness grows proportional to the oxidation rate, the growing oxide thickness is proportional to the square-root of the plasma exposure time. Those skilled in the art refer this to parabolic growth and can be characterized by the equation below:

X²+AX=B(t),

where: X=oxide thickness, t=time, B=parabolic rate constant and A/B=linear rate constant.

Because silicon loss is generally known to be governed by silicon surface oxidation for plasma resist stripping processes, the use of oxygen (O₂) based plasma ashing processes is considered by many to be unacceptable for the 32 nm and beyond technology nodes for advanced logic devices, where almost “zero” substrate loss is required and new materials are being introduced such as embedded SiGe source/drain, high-k gate dielectrics, metal gates and NiSi contact which are extremely sensitive to surface oxidation. For traditional plasma ashing, the parabolic rate constant can be as high as 50 Å²/sec, so in only a few seconds of exposure time, significant oxide growth can occur. Likewise, it has been found that traditional fluorine containing plasma processes, in addition to unacceptable substrate loss, often results in dopant bleaching. Other FEOL plasma ashing processes use reducing chemistries such as forming gas (N₂/H₂), which provides good results as it relates to substrate oxidation but has throughput issues because of its lower resist removal rates. Moreover, hydrogen based plasmas have often been found to induce changes to the dopant distribution, which deleteriously affects the electrical properties of the device.

Because of this, prior plasma mediated ashing processes are generally considered unsuitable for removing photoresist in the FEOL process flow for the advanced design rules. Consequently, much attention has been directed to wet chemical removal of photoresist because of what is perceived as insurmountable problems associated with plasma mediated ashing for these design rules, e.g., substrate loss, dopant bleaching, and the like. As will be demonstrated herein, Applicant's have discovered viable plasma mediated stripping processes suitable for the advanced design rules that provide minimal substrate loss, minimal dopant bleaching, and the like.

It is important to note that ashing processes significantly differ from etching processes. Although both processes may be plasma mediated, an etching process is markedly different in that the plasma chemistry is chosen to permanently transfer an image into the substrate by removing portions of the substrate surface through openings in a photoresist mask. The etching plasma generally exposes the substrate to high-energy ion bombardment at low temperatures and low pressures (of the order of millitorr) to physically remove selected portions of the substrate. Moreover, the selected portions of the substrate exposed to the ions are generally removed at a rate greater than the removal rate of the photoresist mask. In contrast, ashing processes generally refer to removing the photoresist mask and any polymers or residues formed during etching. The ashing plasma chemistry is much less aggressive than etching chemistries and is generally chosen to remove the photoresist mask layer at a rate much greater than the removal rate of the underlying substrate. Moreover, most ashing processes heat the substrate to further increase the plasma reactivity and wafer throughput, and are performed at relatively higher pressures (on the order of a torr). Thus, etching and ashing processes are directed to removal of photoresist and polymer materials for very different purposes and as such, require completely different plasma chemistries and processes. Successful ashing processes are not used to permanently transfer an image into the substrate. Rather, successful ashing processes are defined by the photoresist, polymer, and/or residue removal rates without affecting or removing underlying layers, e.g., the substrate, oxide and nitride spacers, low k dielectric materials, and the like.

Based on the foregoing, what is needed in the art is a viable solution for photoresist removal as is needed for the advanced designed rules especially as it relates to removal of photoresist after a high dose ion implantation processing.

### BRIEF SUMMARY OF THE INVENTION

In one embodiment, a plasma ashing process for removing photoresist, polymers and/or residues from a substrate comprises placing the substrate including the photoresist, polymers, and/or residues into a reaction chamber; generating a plasma from a gas mixture comprising oxygen gas (O₂) and/or an oxygen containing gas; suppressing and/or reducing fast diffusing species in the plasma; and exposing the substrate to the plasma to selectively remove the photoresist, polymers, and/or residues from the substrate, wherein the plasma is substantially free from fast diffusing species.

In another embodiment, a process for ashing organic matter from a substrate comprises generating a plasma from a gas mixture comprising O₂ or oxygen containing gas; combining the plasma with an atomic oxygen scavenging gas; exposing the substrate having the organic matter thereon to the plasma; and selectively removing the organic matter from the substrate.

In yet another embodiment, a plasma apparatus for ashing photoresist, polymers, and/or residues from a substrate, the apparatus comprises a plasma generating component for generating a plasma, wherein the plasma is configured to be substantially free from fast diffusing oxidizing species and is formed from a gas mixture of an oxygen containing gas and an atomic oxygen scavenging gas, a process chamber in fluid communication with the plasma generating component, said process chamber housing the substrate.

In yet another embodiment, a plasma apparatus for ashing photoresist, polymers, and/or residues from a substrate includes a plasma generating component for generating a plasma, wherein the plasma is formed from gas mixtures comprising oxygen gas (O2) or an oxygen containing gas, combined with an atomic oxygen scavenging gas; a scavenging material intermediate the plasma and the substrate configured to suppress and/or reduce fast diffusing species in the plasma; and a process chamber for housing the substrate in fluid communication with the plasma generating component, said process chamber configured to expose the substrate to the plasma having suppressed and/or reduced fast diffusing species therein to selectively remove photoresist, polymers, and/or residues from the substrate.

These and other features and advantages of the embodiments of the invention will be more fully understood from the following detailed description of the invention taken together with the accompanying drawings. It is noted that the scope of the claims is defined by the recitations therein and not by the specific discussion of features and advantages set forth in the present description.

### BRIEF DESCRIPTION OF THE DRAWINGS

The following detailed description of the embodiments of the invention can be best understood when read in conjunction with the following figures, which are exemplary embodiments, in which:

FIG. 1 illustrates a bar chart showing the relative amounts of active nitrogen to active oxygen produced for a prior art plasma formed from oxygen gas (O₂) and nitrogen gas (N₂) compared to plasmas formed in accordance with the present invention, wherein the ratio of active nitrogen to active oxygen is substantially greater than that obtainable from the prior art plasma of oxygen and nitrogen gases.

FIG. 2 graphically illustrates normalized silicon oxide growth as a function of oxygen content in the gas mixture used to form the plasma, wherein the gas composition includes oxygen (O₂) and nitrogen (N₂) mixtures, and oxygen (O₂) and forming gas (H₂/N₂) mixtures.

FIG. 3 schematically illustrates an exemplary plasma apparatus configured to enhance the ratio of active nitrogen to active oxygen, which is then substantially greater than that obtainable from the prior art plasma of oxygen and nitrogen gases

FIG. 4 illustrates a bar chart showing silicon oxide growth and photoresist ashing rates for a nitrous oxide based plasma (N₂O) compared to prior art plasma formed from a gas mixture of oxygen (O₂) and forming gas (N₂/H₂); and another prior art plasma formed from forming gas (N₂/H₂).

FIGS. 5 A-C illustrate a bar chart showing substrate damage for a nitrous oxide-based plasma compared to prior art oxygen-based (O₂) plasmas and scanning electron micrograph images of a post p-MOS high-dose ion implant cleaning application. The substrate damage included (i) silicon loss from silicon-on-insulator (SOI) test structures, (ii) silicon-oxide growth on bare silicon test wafers and (iii) silicon-oxide loss from silicon thermal oxide test wafers. The SEM images in FIGS. 5B and 5C pictorially render top down images after plasma strip followed by de-ionized water rinse for a plasma formed from O₂ and N₂/H₂ gas mixture (b) and a plasma formed from nitrous oxide gas (c).

FIG. 6 illustrates a bar chart showing silicon substrate loss, dopant loss, and photoresist ashing rate as a function of the plasma chemistry for nitrous oxide-based plasmas, forming gas based-plasma, oxygen and forming gas-based plasmas and a H₂/N₂ plasma with high hydrogen content.

FIG. 7 graphically illustrates silicon oxidation as a function of resist removed for nitrous oxide-based plasmas, and an oxygen and forming gas plasma. The graph exemplifies nitrous oxide plasma conditions with and without an active nitrogen enrichment configuration and with an optimized nitrous oxide strip plasma condition.

FIG. 8 graphically illustrates a bar chart showing the relative amounts of active oxygen and active nitrogen and the corresponding ratio of active oxygen and active nitrogen for the nitrous oxides plasmas of FIG. 7 that were obtained with and without the active nitrogen enrichment configuration.

FIG. 9 graphically illustrates plasma optical emission intensity as a function of wavelength for a nitrous oxide based-plasma compared to plasma formed from an oxygen gas and a forming gas.

FIG. 10 graphically illustrates relative amounts of active nitrogen and active oxygen and the corresponding ratio of active nitrogen to active oxygen for nitrous oxide based plasmas at different power settings. Also shown is the corresponding silicon oxide growth for these plasmas.

FIG. 11 graphically illustrates relative amounts of active nitrogen and active oxygen and the corresponding ratio of active nitrogen to active oxygen for nitrous oxide based plasma, nitrous oxide based plasma with CF₄ additive, a plasma formed from O₂ gas and forming gas and a plasma formed from O₂ gas and N₂ gas.

FIG. 12 graphically illustrates the amount of silicon oxidation as a function of the electron temperature for an oxidizing plasma.

FIG. 13 graphically illustrates microwave power as a function of optical emission intensity for plasmas generated from 90% NH₃ and 10% O₂ at different power settings.

FIG. 14 graphically illustrates total gas flow rate and pressure as a function of optical emission intensity for plasmas generated from 90% NH₃ and 10% O₂ at constant power settings.

FIG. 15 graphically illustrates silicon loss and oxide growth as a function of time for plasma generated from oxygen and forming gas; plasma generated from nitrous oxide gas, and plasma generated from ammonia and oxygen gases.

FIG. 16 graphically illustrates relative optical emission spectral intensity as a function of wavelength for plasma generated from an ammonia and oxygen gas mixture compared to plasma formed from an oxygen gas and a forming gas (5% hydrogen gas in N₂).

FIG. 17 graphically illustrates the temperature dependency of the recombination coefficient for quartz and aluminum oxide materials.

FIG. 18 graphically illustrates the normalized concentration of excited molecular oxygen compared active atomic oxygen as a function of plasma source power density.

FIG. 19 graphically illustrates the measured parabolic growth rates from various oxidizing species at 270 C.

FIG. 20 is a table of the atomic oxygen recombination rates of several materials.

FIG. 21 graphically illustrates the incorporation of nitrogen into the surface oxide from a plasma containing a high ratio of N* to O.

Skilled artisans will appreciate that elements in the figures are illustrated for simplicity and clarity and have not necessarily been drawn to scale.

### DETAILED DESCRIPTION OF THE INVENTION

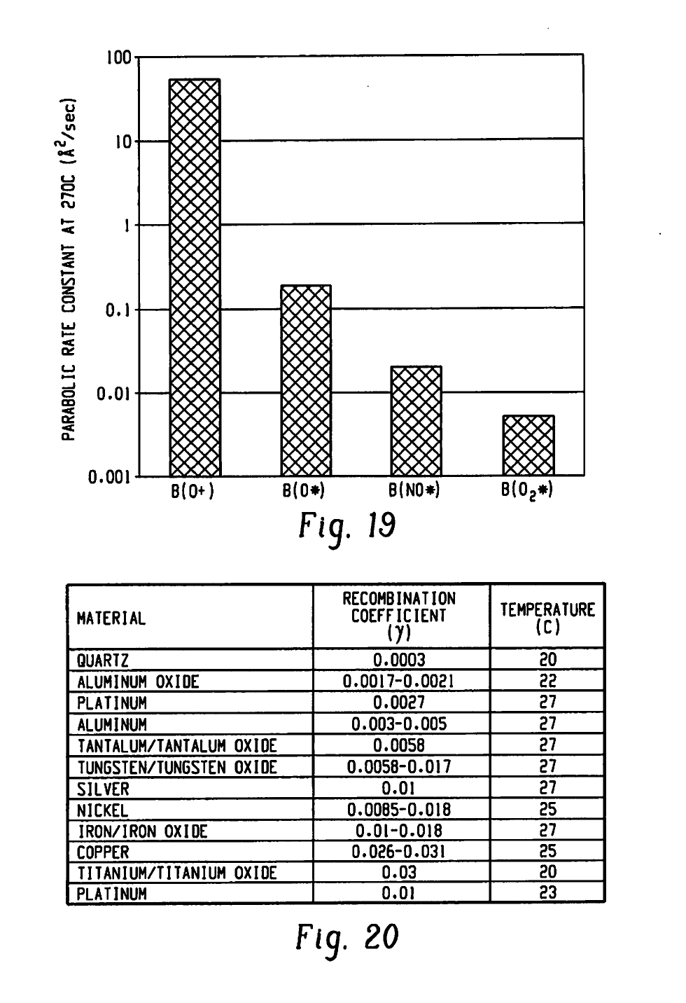

We have characterized the parabolic rate constant, B, for different oxidizing species as shown in FIG. 19. The ionic and atomic species of oxygen have an order of magnitude of higher parabolic rate constant than molecular species such as NO* or O₂*. Given this finding, silicon oxidation can be dramatically reduced by two possible mechanisms: (1) replacing fast diffusing species such as O⁺, O⁻, or O* with substantially slower diffusing, molecular species; (2) nitriding the surface oxide—reducing the diffusion rate of species through the growing oxide.

Disclosed herein are plasma mediated ashing processes and apparatuses for selectively removing photoresist, ion implanted photoresist, polymers, residues, and/or like organic matter from a substrate. As will be described herein, the plasma mediated ashing processes and apparatuses provide a relatively high ashing rate, minimal or no substrate loss, minimal or no damage to underlying materials (e.g., high k dielectric materials), and minimal or no changes to a dopant distribution, among other advantages. As a result, the plasma mediated photoresist ashing processes and apparatuses described herein are suitable for FEOL processing for the 32 nm and beyond technology nodes where substrate loss must be kept to a minimum (less than 1.0 angstroms) and the electrical properties need to be substantially unchanged by the photoresist removal process.

In one embodiment, the plasma mediated ashing processes generally include generating plasma from a gas mixture comprising oxygen gas (O₂) or an oxygen containing gas, wherein the plasma is substantially free from fast diffusing species. Most atomic species formed by plasma generation and used in ashing have high diffusion constants. Atomic species having high diffusion constants have been found to cause high silicon oxidation, an undesirable effect in plasma mediated ashing processes. In other words, the plasma oxidation rate is dominated by fast diffusing species. As such, the term “fast diffusing species,” as used herein, generally refers to atomic species having high diffusion constants, i.e., high parabolic growth rate constants greater than about 0.003 Å²/sec. In one embodiment, a fast diffusing species has a parabolic rate constant at 270 degrees Celsius (° C.) of equal to or greater than about 0.02 Angstroms squared per second (Å²/sec). Exemplary fast diffusing species that can be generated in common plasma processes include, without limitation, active oxygen (O*), atomic oxygen (O), ionic oxygen (O⁻, O⁻), and the like. As used herein, the terms “active nitrogen”, “active oxygen” and other like active species, such as active hydrogen, generally refer to atomic or molecular, energetically excited, but electrically neutral species.

The plasma mediated ashing process disclosed herein is a controlled oxygen diffusion process whereby the diffusion rate as measured by the parabolic rate constant of the fast diffusing species that can oxidize the substrate is reduced or the fast diffusing species are eliminated and/or suppressed from the plasma, during plasma generation or prior to exposure to the substrate to be treated. In order to achieve this, the plasma source, whether generated by microwave or radiofrequency energy, is optimized for molecular species generation, wherein the ratio of slow diffusing molecular species to fast diffusing atomic species is maximized to reduce the effects of the fast diffusers, or the diffusion rate of the fast diffusers is reduced, or both. More specifically the effects of the fast diffusers can be reduced by maximizing, the ratio of O₂* or NO* to active oxygen (O*). Because the presence of active oxygen, which is a natural by-product of oxygen gas or oxide containing gas plasmas, is a mechanism for oxidation, the reduction of active oxygen is highly effective in minimizing silicon oxidation. Additionally the diffusion rate of the fast diffusers can be reduced by nitriding the oxide. More specifically, the diffusion constant can be reduced by maximizing the ratio of active nitrogen (N*) to atomic oxygen (O*).

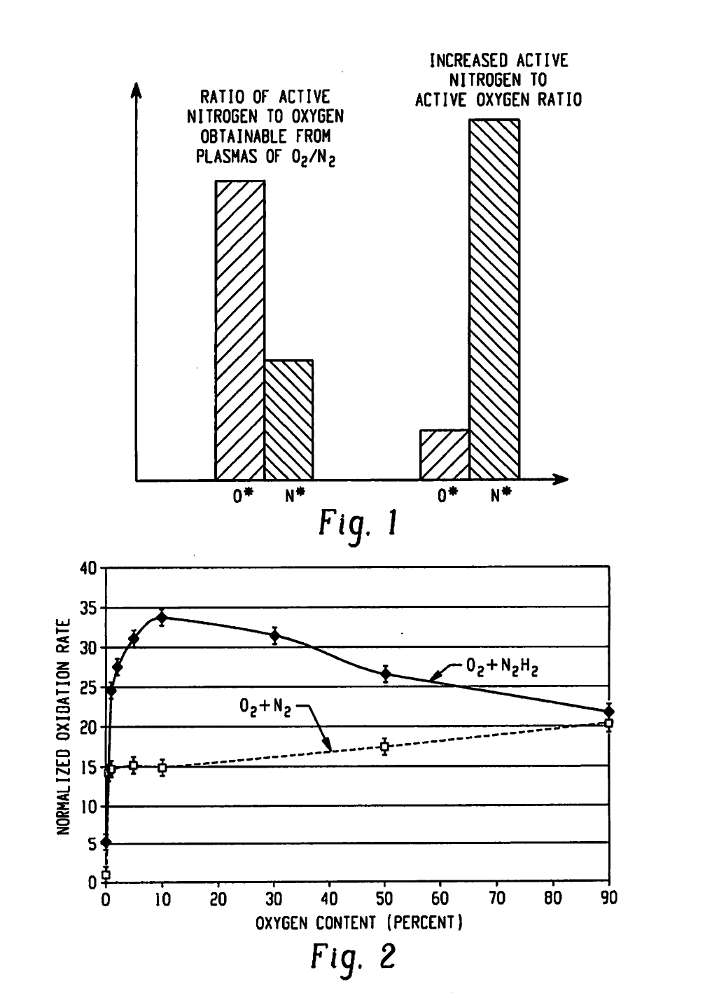

For example, in one embodiment, the plasma mediated ashing processes generally include increasing the ratios of active nitrogen to active oxygen species in the plasma such that the ratios are substantially larger than the active nitrogen species to active oxygen species ratio that is generally obtainable from plasmas of oxygen (O₂) and nitrogen (N₂) gas mixtures. FIG. 1 conceptually illustrates the differences in the obtainable ratio of active nitrogen and active oxygen based on plasmas formed from oxygen (O₂) and nitrogen (N₂) gases and contrasts these ratios with those obtainable by practicing Applicants' invention. As shown at the left side of the graph, prior art plasmas formed from mixtures of oxygen gas and nitrogen gas exhibit a ratio of active nitrogen to active oxygen that includes a relatively higher amount of active oxygen than active nitrogen, which Applicants have discovered is regardless of the particular oxygen and nitrogen gas composition utilized to form the plasma. In contrast, Applicants have discovered various means for increasing the ratio of active nitrogen to active oxygen in the plasma, which is substantially larger than that obtainable from plasmas formed from gas mixtures containing oxygen gas and nitrogen gas.

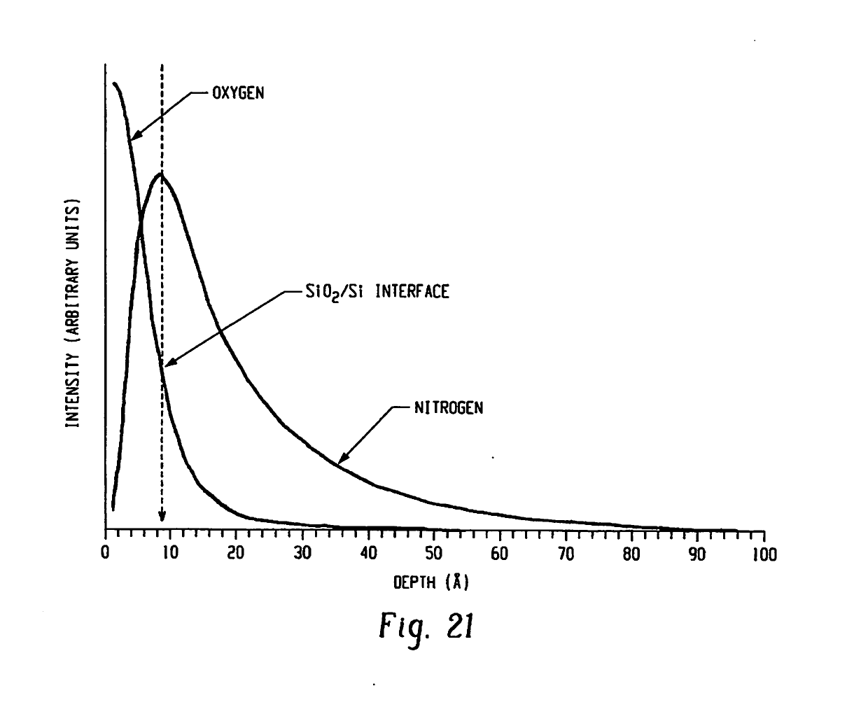

Referring to FIG. 2, there is graphically shown oxide growth as a function of oxygen gas (O₂) content in prior art gas mixtures that include both oxygen (O₂) and nitrogen (N₂) gases for forming the plasma. The evaluated gas mixtures included a mixture containing oxygen gas and nitrogen gas as well as one containing oxygen gas and forming gas, wherein the forming gas contained 3% hydrogen in nitrogen gas. As shown, the impact of active oxygen even at trace amounts provided a deleterious effect on substrate oxidation. The smallest “non-zero” surface modification was observed at 0% oxygen. With regard to the two gas mixtures, a higher oxidation rate was observed for the plasma formed that included forming gas indicating that the active hydrogen species formed within the plasma significantly enhanced silicon oxidation. By changing the active nitrogen to active oxygen ratio, Applicants have unexpectedly discovered a means in which surface oxidization can be minimized while providing effective removal of photoresist. For comparative purposes, plasma formed from a gas containing both nitrogen and oxygen elements, e.g., nitrous oxide, exhibited less than about 4 Angstroms of oxide growth as a function of oxygen content under similar conditions, which was significantly lower than the amount of oxidation using plasmas formed from oxygen and nitrogen gas mixtures. The main mechanism for this reduction in oxidation is a subsequent reduction of the diffusion rate of atomic oxygen by the atomic nitrogen. It has been found, as shown in FIG. 21, that the atomic nitrogen accumulates at the Oxide-Silicon interface and blocks the diffusion of atomic oxygen.

In one embodiment, the plasma mediated ashing process generally includes generating reactive species comprising active nitrogen and active oxygen from a gas mixture and exposing a substrate to the reactive species. The particular components of the plasma gas mixture generally depend on the particular embodiment employed for changing the active nitrogen to active oxygen ratio. For example, the plasma can be generated from gaseous nitrous oxide by itself or a mixture of the nitrous oxide gas with fluorine bearing gases, an oxidizing gas, an inert gas, a reducing gas, and various combinations thereof. In addition, the nitrous oxide gas or nitrous oxide gas mixture may further include various additives to increase photoresist removal rates and/or to minimize damage to the underlying materials, e.g., dielectric materials, substrate, metals, dopant concentration, and the like. It should be noted that although nitrous oxide is specifically referenced above as being suitable for increasing the ratio of active nitrogen to active oxygen in a plasma relative to one obtained using oxygen (O₂) and nitrogen (N₂) gases, other gases are contemplated that include oxygen gas and oxide containing.

Still further, the mixture can be formed from two or more plasmas that are combined in the process chamber. For example, plasma formed from an oxygen containing gas can be mixed with a plasma formed of a nitrogen containing gas. In this manner, one of the plasmas can be formed from oxygen gas (O₂) and the other plasma can be formed from a nitrogen containing gas that provides increased active nitrogen. Conversely, one of the plasmas can be formed from nitrogen gas (N₂) and the other plasma can be formed from an oxygen containing gas.

In yet another embodiment, the addition and presence of active hydrogen species (H*) in combination with the active nitrogen (N*) and optionally active oxygen (O*) species can be beneficial for some applications, e.g., in some post implant applications especially as it relates to residue removal; and in some high K/metal gate structures where metal oxidation can affect device performance. By providing a plasma of a controlled mixture of active nitrogen, active hydrogen species, and optionally active oxygen, low substrate damage (e.g., Si oxidation and/or Si loss) and low metal substrate oxidation (e.g., TiN, TaN, and/or W metals) is provided while effectively removing photoresist and residue at relatively high throughputs. In some embodiments, the plasma is formed from a gas consisting of NH₃. In other embodiments, the plasma is formed from a gas mixture including NH₃, wherein NH₃ constitutes the major portion of the gas mixture. By way of example, the gas mixture can include greater than 50% NH₃ is some embodiments, greater than 75% in other embodiments and greater than 85% in still other embodiments. For most ashing applications, greater than or equal to 90% NH₃ in the gas mixture is preferred. Exemplary gas mixtures include, without limitation, NH₃ and forming gas, NH₃ and N₂, and NH₃, forming gas and oxygen. The presence of oxygen increases the ashing rate and by controlling the amount of oxygen present in the gas mixture, minimal silicon loss is observed while providing a high throughput process.

As will be discussed in greater detail herein, the various means for decreasing the fast diffusing species (e.g., atomic oxygen species) in the plasma include the use of filters, scavenging gases, scavenging materials or gettering agents, and the like to remove and/or absorb the fast diffusing species generated in the plasma upon excitation of O₂ and prior to exposure to the photoresist, thereby, decreasing the amount of fast diffusing species within the plasma. Additionally, these gettering materials produce excited state molecular oxygen, which is effective in removing photoresist without oxidation of substrate materials. Alternatively, the plasma source and gas mixture can be chosen to maximize the ratio of slow diffusing oxidizers such as molecular oxidizers to fast diffusing oxidizers such as atomic or ionic oxygen, which can be in combination with any of the enhancement methods noted above or by itself. By doing so, the plasma can further include active hydrogen species, which have been found to provide the plasma with a more aggressive ashing behavior of the ion implanted resist crust with minimal damage, e.g., substrate oxidation, substrate erosion, and the like. The more aggressive ashing behavior can be used to efficiently ash photoresist materials that are typically considered difficult to ash such as for example a crust layer formed in the photoresist after exposure to high energy dose ion implantation (HDIS), post etch residues, and the like.

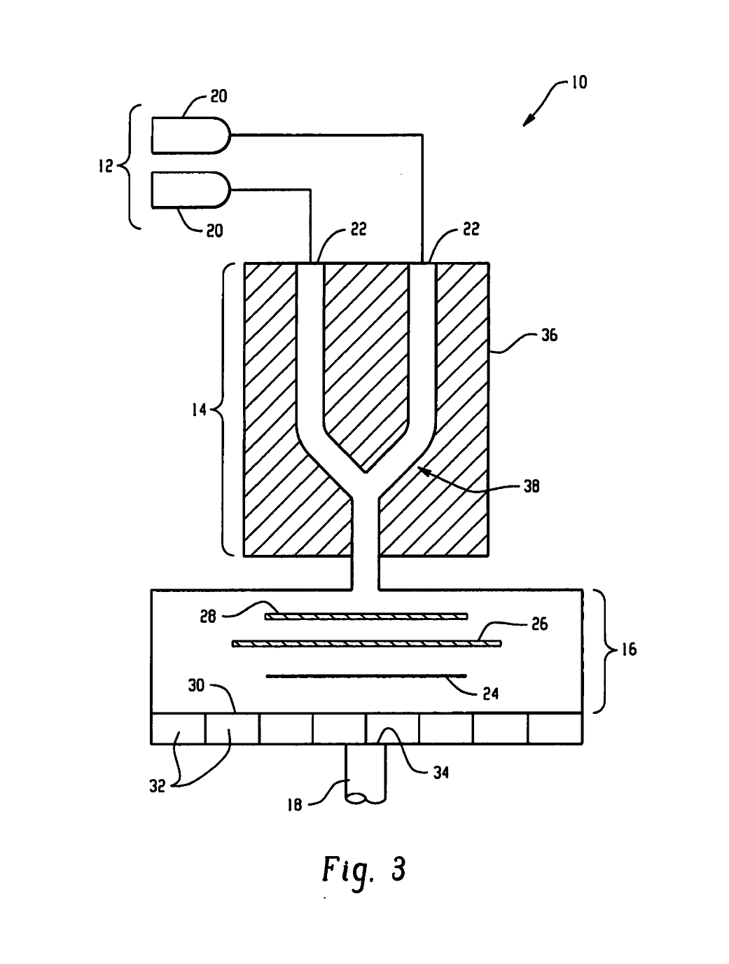

FIG. 3 illustrates an exemplary apparatus for generating multiple plasma streams generally designated by reference numeral 10. The plasma apparatus 10 generally includes a gas delivery component 12, a plasma generating component 14, a processing chamber 16, and an exhaust tube 18. The gas delivery component 12 may include a gas purifier (not shown) in fluid communication with one or more gas sources 20 that are in fluid communication with the plasma generating component. Using microwave excitation as an example of a suitable energy source for generating the plasma from a gas mixture, the plasma generating component 34 includes a microwave enclosure 36, which is generally a partitioned, rectangular box having the plasma tube 38 passing therethrough. As is known in the art, the microwave plasma generating component 14 is configured to cause excitation of the input gas into a plasma so as to produce reactive species. In addition to microwave energy, the plasma generating component 304 could also be operated with an RF energy excitation source, a combination of RF and microwave energy, or the like. The plasma tube 38 includes a one or a plurality of gas inlet openings 22, two of which are shown, into which the gases 20 from the gas delivery component 12 are fed. The plasma tube portions extending from the gas inlet openings are connected downstream from the plasma energy source. In this manner, different plasmas are generated within the apparatus, which are then mixed prior to exposing the substrate.

Once excited, the active species are introduced into an interior region of the processing chamber 16 for uniformly conveying the reactive species to the surface of a workpiece 24, such as a resist-coated semiconductor wafer. In this regard, one or more baffle plates 26, 28 are included within the processing chamber 16. Although the specific manner of operation of the baffle plates is not described in further detail hereinafter, additional information on such operation may be found in U.S. patent application Ser. No. 10/249,964 to Axcelis Technologies, Inc., incorporated herein by reference in its entirety. In order to enhance the reaction rate of the photoresist and/or post etch residue with the active species produced by the upstream plasma, the workpiece 24 may be heated by an array of heating elements (e.g., tungsten halogen lamps, or a resistively heated chuck, not shown in the figures). An inlet 34 of the exhaust tube 18 is in fluid communication with an opening in the bottom plate for receiving exhaust gas into the exhaust tube 18.

Again, it should be understood that the plasma asking apparatus 10 represents an example of one such device that could be used in conjunction with practicing the invention so as to generate different plasmas from different gas streams that are subsequently mixed prior to exposing the substrate to the plasma. Other suitable plasma apparatuses include medium pressure plasma system (MPP) operating at about 100 Torr so as to provide lower electron temperatures as well as single plasma tube configurations and those plasma sources without baffles such as wide source area plasmas.

Suitable nitrogen containing gases where applicable for the different embodiments include, without limitation, N₂, N₂O, NO, N₂O₃, NH₃, NF₃, N₂F₄, C₂N₂, HCN, NOCl, ClCN, (CH₃)₂NH, (CH₃)NH₂, (CH₃)₃N, C₂H₅NH₂, mixtures thereof, and the like.

Suitable inert gases for addition to the gas mixture include, without limitation, helium, argon, nitrogen, krypton, xenon, neon, and the like.

Suitable fluorine bearing gases, where active fluorine is desired, include those gaseous compounds that generate fluorine reactive species when excited by the plasma. In one embodiment, the fluorine gaseous compound is a gas at plasma forming conditions and is selected from the group consisting of a compound having the general formula CₓH_{y}F_{z}, wherein x is an integer from 0 to 4 and y is an integer from 0 to 9 and z is an integer from 1 to 9 with the proviso that when x=0 then y and z are both are equal to 1, and when y is 0 then x is 1 to 4 and z is 1 to 9; or combinations thereof. Alternatively, the fluorine bearing gas is F₂, SF₆, and mixtures thereof including, if desired, the fluorine bearing gases defined by the general formula CₓH_{y}F_{z} above.

The fluorine-bearing gases, when exposed to the plasma, are less than about 5 percent of the total volume of the plasma gas mixture to maximize selectivity. In other embodiments, the fluorine-bearing compounds, when exposed to the plasma, are less than about 3 percent of the total volume of the plasma gas mixture. In still other embodiments, the fluorine-bearing compounds, when exposed to the plasma, are less than about 1 percent of the total volume of the plasma gas mixture.

Suitable reducing gases include, without limitation, hydrogen bearing gases such as H₂, CH₄, NH₃, CₓH_{y}, wherein x is an integer from 1 to 4 and y is an integer from 1 to 8, and combinations thereof. The hydrogen bearing compounds used are ones that generate sufficient atomic hydrogen species to increase removal selectivity of the polymers formed during etching and etch residues. Particularly preferred hydrogen bearing compounds are those that exist in a gaseous state and release hydrogen to form atomic hydrogen species such as free radical or hydrogen ions under plasma forming conditions. The hydrocarbon based hydrogen bearing compounds gas or may be partially substituted with a halogen such as bromine, chlorine, or fluorine, or with oxygen, nitrogen, hydroxyl and amine groups.

The hydrogen gas (H₂) is preferably in the form of a gas mixture. In one embodiment, the hydrogen gas mixtures are those gases that contain hydrogen gas and an inert gas. Examples of suitable inert gases include argon, nitrogen, neon, helium and the like. Especially preferred hydrogen gas mixtures are so-called forming gases that consist essentially of hydrogen gas and nitrogen gas. Particularly preferred is a forming gas, wherein the hydrogen gas ranges in an amount from about 1 percent to about 5 percent by volume of the total forming gas composition. Although amounts greater than 5 percent can be utilized, safety becomes an issue due to risk of explosion of the hydrogen gas.

Suitable oxidizing gases include, without limitation, O₂, O₃, CO, CO₂, H₂O, N₂O, NO₂, and the like. When using oxidizing gases, it is preferred to remove any O* and O− species from the plasma, as described above, prior to exposure to the substrate. As noted above, it has been found that a causal factor of substrate oxidation is the reaction of the substrate with O*, O⁺ and/or O⁻ species. These species can easily diffuse through a growing SiOx surface oxide, thereby resulting in relatively thicker oxide growth. Additionally, the fast diffusion of these species can be enhanced by electric fields present or induced in the surface oxide. Because of this, a strategy for minimizing oxide growth should address several issues, namely: suppress atomic or ionic oxygen formation (or the formation of any other fast diffusing species), reduce the diffusion rate of the remaining fast diffusers, and reduce or eliminate electric fields and oxide charging. As noted above, removal can be effected by increasing pressure within the reaction chamber during plasma processing, varying the power density, the addition of additives, addition of gases that contain both nitrogen and oxygen elements (e.g., nitric oxide), and the use of filters, e.g., atomic and ionic filters.

The plasma mediated ashing process can be practiced in conventional plasma ashing systems. The invention is not intended to be limited to any particular hardware for plasma ashing. For example, a plasma asher employing an inductively coupled plasma reactor could be used or a downstream plasma asher could be used, e.g., microwave driven, Rf driven, and the like. The settings and optimization for particular plasma ashers will be well within the skill of those in the art in view of this disclosure. Plasma ashers generally are comprised of a plasma generating chamber and a plasma reaction chamber. For exemplary purposes only, in a 300 mm RpS320 downstream microwave plasma asher available from Axcelis Technologies, Inc., the present assignee, the substrates are heated in the reaction chamber to a temperature between room temperature and 450° C. The temperatures used during processing may be constant or alternatively, ramped or stepped during processing Increasing the temperature is recognized by those skilled in the art as a method to increase the ashing rate. The pressure within the reaction chamber is preferably reduced to about 0.1 Torr or higher. More preferably, the pressure is operated in a range from about 0.5 Torr to about 4 Torr. In some applications such as where gas phase recombination of undesired oxygen species (e.g., O*, O−) is desired so as to increase the ratio of active nitrogen to active oxygen in the plasma, higher operating pressures greater than 4 torr can be utilized, with greater than 10 torr used in some embodiments.

The power used to excite the gases and form the plasma energy source is generally between about 1000 Watts (W) and about 10000 W. For some gas mixtures, the power greater than 5000 W to less than about 10000 W. For example, when the gas mixture includes NH₃ as the primary component (greater than 50%), it has been found that increasing the power to greater than 5000 W to less than 10000 W can be used to increase the amount of active hydrogen formed within the plasma, which can advantageously provide an increase in the ashing rate. In addition, the increased amount of active hydrogen species reduces metal oxidation. In some embodiments, the plasma is exposed to a gettering agent so as to reduce the amount of active hydrogen when desired. The power setting can also be adjusted to control the ratio of active nitrogen to active oxygen in the plasma, which is applicable to other types of plasma ashing tools.

The power density, i.e., the power per volume of gas, in the plasma source can also be adjusted to increase the amount of neutral and excited state molecular species (e.g., O₂, O₂*, and the like). In one embodiment, the plasma can be generated at a power density of at least about 75 watts per centimeter cubed (W/cm³); specifically at least about 100 W/cm³, more specifically at least about 150 W/cm³, still more specifically at least about 200 W/cm³, and most specifically at least about 300 W/cm³.

The gas mixture comprising NH₃, oxygen or oxygen and nitrogen and, in some embodiments, a hydrogen-bearing gas, is fed into the plasma-generating chamber via a gas inlet. The gases are then exposed to an energy source within the plasma-generating chamber, e.g., microwave energy, preferably between about 1000 W and about 10000 W, to generate excited or energetic atoms from the gas mixture. The generated plasma is comprised of electrically neutral and charged particles and excited gas species formed from the gases used in the plasma gas mixture. In one embodiment, the charged particles are selectively removed prior to plasma reaching the wafer.

The total gas flow rate is preferably from about 500 to 12,000 standard cubic centimeters per minute (sccm) for the 300 mm downstream plasma asher. It has been found that the total gas flow rate can influence the emission spectrum for some of the gas mixtures. For example, a lower total gas flow rate may be preferred for gas mixtures comprising NH₃ as the major component to increase the amount of active hydrogen in the plasma and increase the concentration of active molecular species. In one embodiment, the total gas flow rate of the NH₃ containing gas or gas mixtures is less than 5 standard liters per minute (slm). In other embodiments, less than 4 slm, and in still other embodiments, less than 3.5 slm.

The photoresist, ion implanted photoresist, polymers, residues, or like organic matter can be selectively removed from the substrate by reaction with the excited or energetic atoms (i.e., active species) generated by the plasma. The reaction may be optically monitored for endpoint detection as is recognized by those in the art. Optionally, a rinsing step is performed after the plasma ashing process so as to remove the volatile compounds and/or rinse removable compounds formed during plasma processing. In one embodiment, the rinsing step employs deionized water but may also include ammonium hydroxide, sulfuric acid or hydrofluoric acid and the like. The rinsing step, if applied, can include a spin rinse for about 1 to 10 minutes followed by spin drying process.

By way of example, modifications to the plasma hardware configurations can be made to increase the active slow diffusing species to the fast diffusing species or increase the active nitrogen to active oxygen ratio. In one embodiment, a scavenging material such as an atomic and/or ionic oxygen filter and/or catalyst material is disposed intermediate the substrate and the plasma source so as to generate the excited-state molecular oxygen and to decrease the amount of fast diffusing species in the plasma. This filter can be a catalytic filter and/material, a surface recombination filter, a gas-phase recombination filter or the like. By way of example, the filter can be a surface reactive metals or metallic alloys, ceramics, quartz or sapphire materials for which the reactive gas passes over prior to interacting with the wafer surface. The effectiveness of this filter can be enhanced by controlling the temperature of the reactive surface as well as the shape and surface roughness of the reactive surface. This scavenging material can be located in close proximity to the substrate, since the excited-state molecules have relative short lifetimes. More specifically, the scavenging material can be located within about 8 cm or less from the work-piece (substrate).

In another embodiment, plasma ashing tools utilizing a dual baffle plate are modified such that the upper baffle plate is formed of quartz as opposed to sapphire, which has also been found to increase the ratio of active nitrogen to active oxygen. A similar effect is observed by forming the plasma tube of sapphire or other materials instead of quartz. Suitable scavenging materials that can be used to reduce the fast diffusing species content in the plasma, specifically the O, O*, O+, and/or O− content, are those materials having a recombination coefficient of equal to or greater than about 5×10⁻⁴.

Exemplary materials for scavenging atomic oxygen are listed in the table of FIG. 20, but may also include, without limitation: metals such as B, Mg, Al, Ag, Be, Ti, Cr, Fe, Mn, Ni, Rb, Ir, Pb, Pt, Sr, Ba, Cs, alloys thereof, or intermetallic compounds such as PrNi₅, Nd₂Ni₁₇, and the like, or ceramics such as TiO₂, Ta₂O₅, ZrO₂, Al₂O₃, FeO and the like, or semiconductors such as Si, Ge, and the like, or organometallics. Exemplary atomic oxygen scavenging gases include without limitation: gases such as NH₃, CO, NO, CH₄, other hydrocarbons, fluorocarbons, and the like, Suitable catalysts for the formation of active nitrogen include, without limitation, metals such as Fe, Co, Ni, Ru, Re, Pt, Mo, Pd and the like or ceramics such as MgAl₂O₄ and the like. Active nitrogen formation can also be promoted by employing gas additives such as He, Ar, Kr, Xe, or by elements of design of the plasma source, such as plasma source surface materials and temperature, or by method of operation of the plasma source, such as excitation frequency, power density, electron temperature, gas mix ratio, or there like.

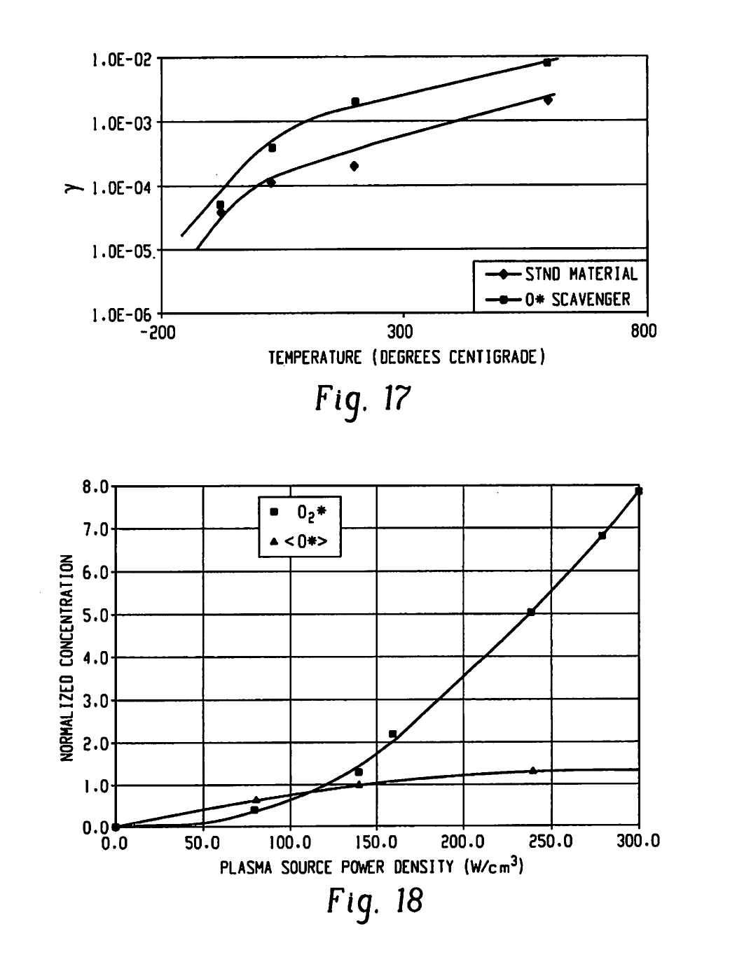

In another embodiment, the scavenging material is heated either directly or indirectly to a temperature of about 200° C. or higher to enhance the atomic oxygen recombination. FIG. 17 graphically depicts the increase in recombination of AL₂O₃, and SiO₂ as a function of temperature. The recombination rate of most materials increases at elevated temperatures.

In another embodiment, a scavenging gas can be used in place of or in addition to a scavenging and/or gettering material. An atomic oxygen scavenging gas can be combined with the plasma sources described above, wherein the scavenging gas is effective in further reducing the atomic oxygen content by at least a factor of 4. An exemplary scavenging gas for further reducing fast diffusing species is NH₃, wherein the NH₃ to O₂ ratio would exceed 2-to-1 in the gas mixture.

In another embodiment, a downstream plasma asher that selectively removes charged particles prior to exposure of the reactive species to the substrate is utilized, such as for example, downstream microwave plasma ashers commercially available under the trade name RpS320 from the Axcelis Technologies, Inc. in Beverly, Mass. For FEOL processing, it is generally desirable to remove substantially all of the charged particles from the reactive species prior to exposing the substrate to the reactive species. In this manner, the substrate is not exposed to charged particles that may deleteriously affect the electrical properties of the substrate. The substrate is exposed to the electrically neutral reactive species to effect photoresist, polymer, and/or residue removal, i.e., active species of nitrogen (N*), oxygen (O*), optionally (H*) and the like in accordance with the present invention.

An additional/emerging requirement for the advance design rules is the need to maintain compatibility of the plasma ashing process with high-k dielectrics and metal gate materials. To promote compatibility, the nitrous oxide gas mixture or any of the various means discussed above that can be used increase the active nitrogen to active oxygen ratio may include additives chosen to reduce damage to these materials while maintaining sufficient reactivity to remove the photoresist and implanted crust materials. Suitable chemistry additives include, without limitation, halogen containing materials such as CF₄, CHF₃, C₂F₆, HBr, Br, HCl, Cl₂, BCl₃, CH₃Cl, CH₂Cl₂, and the like.

The halogen containing additives discussed above can be effectively used to enhance removal of the portion of the photoresist layer referred to as the crust of an ion implanted photoresist. In other embodiments, plasmas including active nitrogen, active oxygen, and active hydrogen species can be used to effectively remove the crust. By way of example, the plasma can be formed from gas mixtures of NH₃, O₂, and forming gas which effectively removes the crust and underlying photoresist. In other embodiments, a multi-step plasma ashing process can be used to remove the crust followed with an aggressive plasma chemistry followed by a less aggressive plasma chemistry so as to remove the underlying non-crosslinked photoresist, polymers, and residues, which is optionally be followed by a passivation or residue removal plasma step. For example, to protect the gate electrode and/or gate dielectric during plasma ashing of an ion implanted photoresist, a first step could include forming plasma with a nitrous oxide gas mixture that includes a halogen containing additive to remove the photoresist crust, followed by a plasma ashing step that includes forming the plasma with gaseous nitrous oxide only, i.e., a much less aggressive plasma than one containing the halogen containing additive. It should be noted that one or more of the multiple plasma steps do not require that the plasma have a ratio of active nitrogen and active oxygen that is larger than a ratio of active nitrogen and active oxygen obtainable from plasmas of oxygen gas and nitrogen gas. In some embodiments, only one of the multiple steps includes generating the plasma with the desired higher active nitrogen to active oxygen ratio.

The plasma mediated ashing process can be used to effectively ash, i.e., remove, photoresist, ion implanted photoresist, polymers, and/or post etch residues from the semiconductor substrate with minimal substrate loss and minimal dopant bleaching, dopant profile changes, or dopant concentration changes, among other advantages. Advantageously, the plasma ashing processes described herein can be optimized to have ashing selectivity greater than 10,000:1 over silicon.

In one embodiment, the process is a multi-step process that is effective for removing ion implanted photoresist. As noted above, ion implanted photoresist generally includes an upper portion and a lower portion, wherein the upper portion has a higher crosslinking density than the lower portion as a function of exposure to ion implantation. The multi-step process can include a first step of removing substantially the entire upper portion by exposing the photoresist layer to a low density plasma of less than about 70 W/cm³ formed from a gas mixture comprising NH₃, wherein the NH₃ constitutes a major portion of the gas mixture. The lower portion can then be removed using different plasma. For example, the lower portion can be removed by exposing the photoresist layer to a high density plasma of at least about 70 W/cm³ formed from a gas mixture comprising NH₃, wherein the NH₃ constitutes a major portion of the gas mixture. Any potentially remaining residues can then optionally be removed using different plasma, free of NH₃ such as, for example, a plasma formed from a gas mixture of nitrogen gas or forming gas. The surface may also be passivated, if desired.

Photoresists are generally organic photosensitive films used for transfer of images to an underlying substrate. The present invention is generally applicable to ashing those photoresists used in g-line, i-line, DUV, 193 nm, 157 nm, e-beam, EUV, immersion lithography applications or the like. This includes, but is not limited to, novolaks, polyvinylphenols, acrylates, acetals, polyimides, ketals, cyclic olefins or the like. Other photoresist formulations suitable for use in the present invention will be apparent to those skilled in the art in view of this disclosure. The photoresist may be positive acting or negative acting depending on the photoresist chemistries and developers chosen.

The substrate can essentially be any semiconductor substrate used in manufacturing integrated circuits. Suitable semiconductor substrates generally include or may contain silicon; strained silicon; silicon germanium substrates (e.g., SiGe); silicon on insulator, high k dielectric materials; metals such as W, Ti, TiN, TaN, and the like; GaAs; carbides, nitrides, oxides, and the like. Advantageously, the process is applicable to any device manufacture where loss of material from the semiconductor substrate such as over a doped region is not desirable.

The following examples are presented for illustrative purposes only, and are not intended to limit the scope of the invention.

### Example 1

In this example, photoresist coated onto a silicon substrate was exposed to a nitrous oxide stripping chemistry in a RapidStrip320 plasma ashing tool commercially available from Axcelis Technologies, Inc. The photoresist was an i-line photoresist and was deposited onto the silicon substrate at a thickness of 1.9 microns. The plasma chemistry was formed by flowing nitrous oxide gas at 7 standard liters per minute (slm) into the plasma ashing tool at a pressure of 1 Torr, a temperature of 240° C., and a power setting of 3500 Watts.

Ashing rate, cross wafer uniformity, and oxide growth of the nitrous oxide plasma stripping process was compared with oxygen-free reducing plasma (forming gas) and an oxygen based plasma. The reducing plasma was formed from a gas mixture of forming gas (3% hydrogen in nitrogen) at a flow rate of 7 slm into the plasma ashing tool at a pressure of 1 Torr, a temperature of 240° C. and a power setting of 3500 Watts. The oxygen based plasma was formed using 90% oxygen (O₂) and 10% forming gas (3% hydrogen in nitrogen) at 7 slm into the plasma ashing tool at a temperature of 240° C. and a power setting of 3500 Watts.

Ashing rate and non-uniformity was measured after exposure of the photoresist to the respective plasma for 8 or 15 seconds. Oxide growth was measured by exposing uncoated silicon substrates to the respective plasma for 300 seconds.

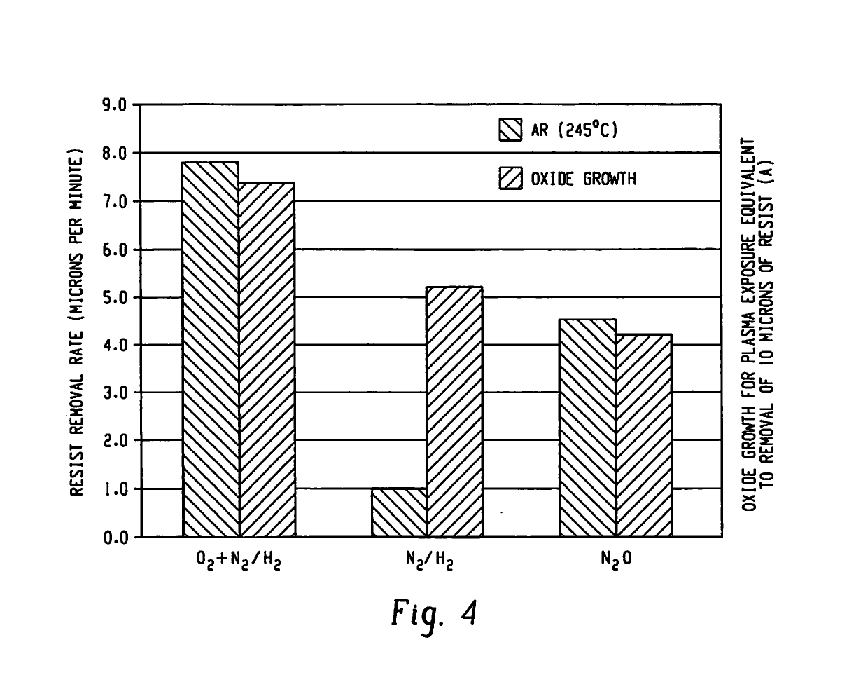

FIG. 4 illustrates the results. As expected, oxide growth for the oxygen based plasma was significant at about 12 angstroms (A) and exhibited the highest ashing rate at about 7.8 μm/min. In contrast, the reducing plasma and the nitrous oxide plasma showed a significant improvement relative to the oxygen based plasma but had lower ashing rates. The nitrous oxide based plasma compared to the reducing plasma exhibited less oxide growth; about 3.0 Å for the nitrous oxide based plasma compared to about 4 Å for the reducing plasma. Notably, the nitrous oxide based plasma exhibited an ashing rate of about 4.4 μm/min compared to about 1.0 μm/min for the reducing plasma. Also, ashing non-uniformity for the nitrous oxide based plasma (non-uniformity=2.8%) was significantly better than the oxygen/forming gas (>10%) under the same processing conditions.

### Example 2

In this example, a small amount of CF₄ was added to different plasma gas mixtures and processed in the RapidStrip320 plasma ashing tool. Silicon substrates were exposed to the different plasma chemistries and oxide growth was measured. The results are shown in Table 1 below. In each instance, the various plasmas were formed using a flow rate of the gas mixture of 7 slm into the plasma ashing tool at a pressure of 1 Torr, and a power setting of 3500 Watts.

TABLE 1

| | Process Time | |
|---|---|---|
| Plasma Chemistry | (seconds) | Oxide Growth (Å) |
| CF₄/N₂O | 103 | 3.24 |
| CF₄/3% O₂/Forming Gas | 103 | 9.54 |
| CF₄/90% O₂/Forming Gas | 103 | 8.76 |
| 3% O₂/Forming Gas | 140 | 9.82 |

As shown, the addition of small amounts of CF₄ during formation of the plasma resulted in minimal substrate loss as evidenced by the oxide growth, and advantageously, can be expected to produce more energetic species, which should effectively increase the ashing rate relative to the results observed in Example 1. The plasma of CF₄/N₂O had the highest active nitrogen to active oxygen ratio, which also exhibited the least amount of oxidation.

### Example 3

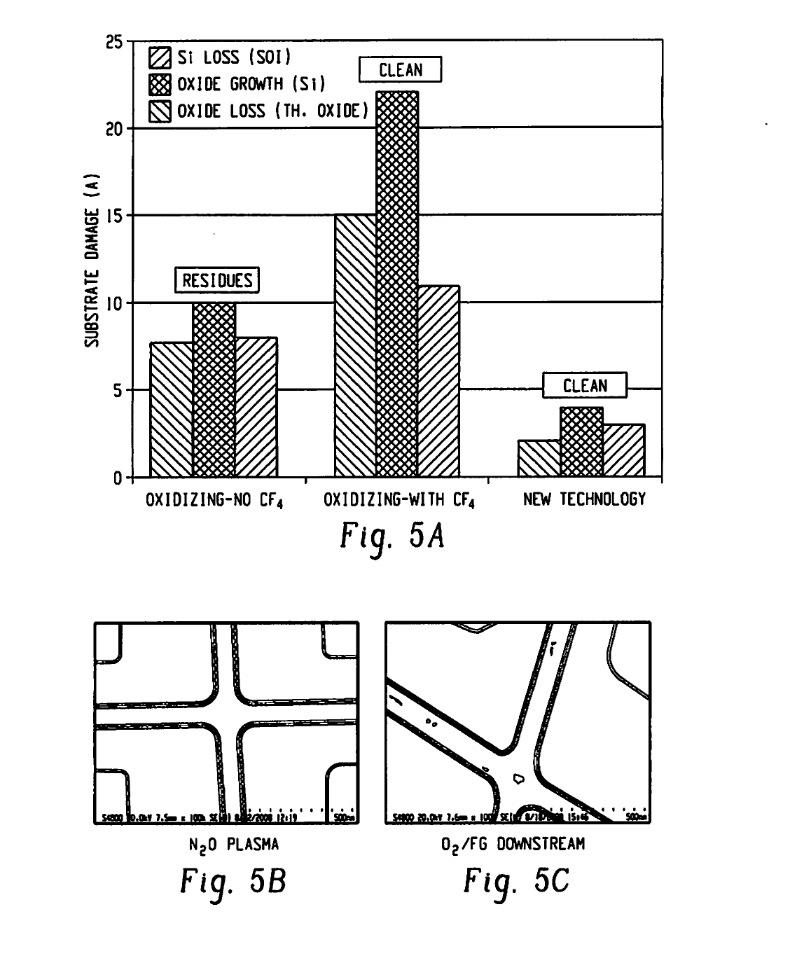

In this example, substrate damage was measured using the RapidStrip320 plasma ashing tool in terms of silicon loss, oxide growth and oxide loss for a plasma formed from nitrous oxide (i.e., labeled as new technology), which was compared to prior art plasmas formed from O₂/forming gas mixtures with and without a small amount of carbon tetrafluoride. The forming gas composition was 3% hydrogen in nitrogen. The results are graphically shown in FIG. 5A. In each instance, the various plasmas were formed using a flow rate of the gas mixture of 7 slm into the plasma ashing tool at a pressure of 1 Torr, a temperature of 240° C. and a power setting of 3500 Watts. The substrate damage included (i) silicon loss from silicon-on-insulator (SOI) test structures, (ii) silicon-oxide growth on bare silicon test wafers and silicon-oxide loss from silicon thermal oxide test wafers. Panels (b) and (c) compare scanning electron micrograph images of a post p-MOS high-dose ion implant cleaning application. The SEM images are shown after plasma strip followed by de-ionized water rinse for a plasma formed from O₂ and N₂/H₂ gas mixture (c) and a plasma formed from nitrous oxide gas, indicating substantially improved residue removal capability of the plasma from the nitrous oxide gas mixture.

The results clearly show a substantial decrease in substrate damage for the plasma having the relatively high active nitrogen to active oxygen ratio. Residues were observed from the oxidizing plasma without carbon tetrafluoride. Moreover, as noted in FIGS. 5B and 5C, residue removal was significantly improved using the nitrous oxide plasma.

### Example 4

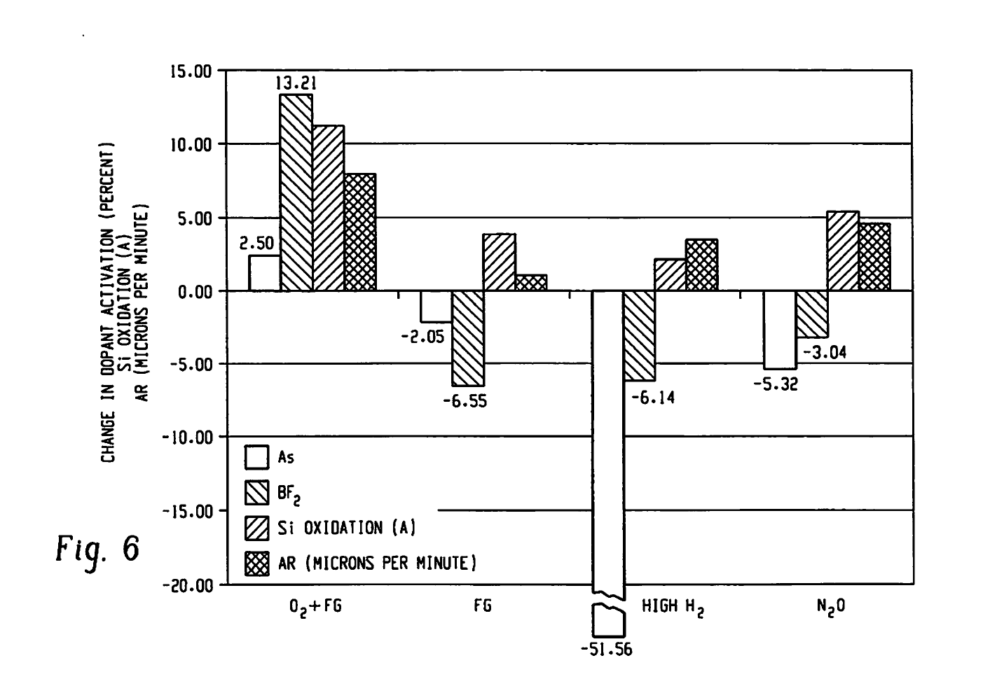

In this example, dopant loss, substrate loss, and ashing rate were monitored during plasma processing using plasmas formed from nitrous oxide gas, forming gas (3% H₂, 97% N₂), oxygen gas (90%) and forming gas (10%), and forming gas with a high amount of hydrogen gas (i.e., a mixture of 90% H₂ and 10% N₂). All plasmas were formed with 7 slm of total gas flow and 3500 W of microwave power. The substrates were heated to a temperature of 240° C. during the plasma processing. The silicon oxidation process time was 5 minutes. The process time to determine resist removal was 8 seconds or 15 seconds. For the dopant profile tests, blanket silicon wafers were implanted with either As or BF₂ following standard recipes. The wafers were then exposed to the various ash plasmas for 5 minutes and annealed at 1050° C. for 10 seconds. Secondary ion mass spectroscopy (SIMS) analysis was performed to determine the dopant profile, and sheet resistance (Rs) measurements were performed to determine the sheet resistance. The results are graphically shown in FIG. 6.

As shown, the plasma formed using the highest active nitrogen to active oxygen ratio exhibited robust behavior for both As and BF₂ implantation in addition to a relatively high ashing rate and low oxidation rate. Moreover, as expected, the plasma formed from a gas mixture that includes oxygen gas exhibited unacceptably high silicon oxidation.

### Example 5

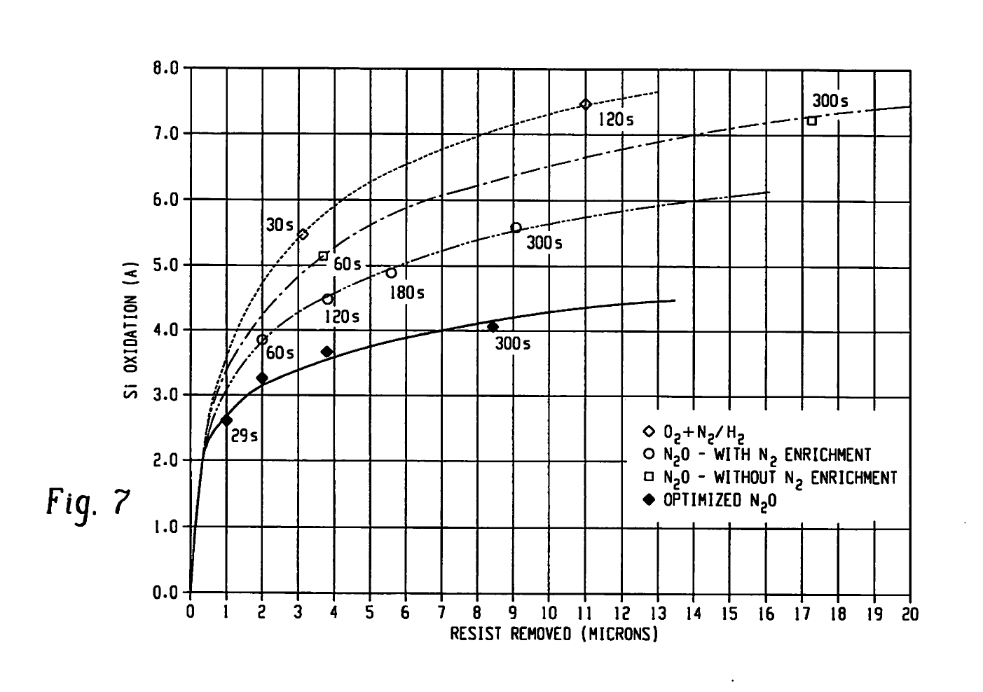

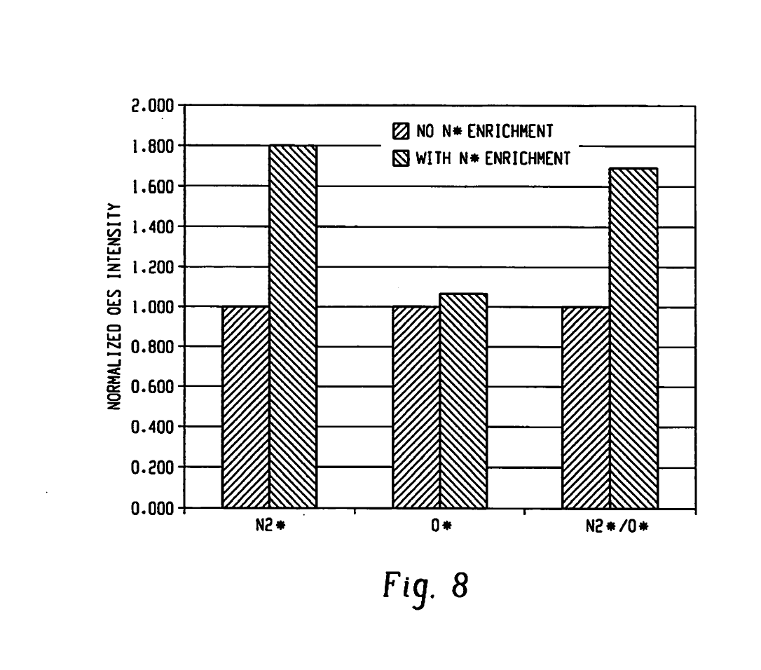

In this example, the effect of an active nitrogen enriching configuration is illustrated. Configuring the RPS320 plasma source with a sapphire tube (active nitrogen enriching configuration) did result in reduced silicon oxidation (FIG. 7) compared to the configuration with a quartz tube (non-nitrogen-enriching configuration). FIG. 8 shows that this exemplary nitrogen-enriching configuration (a sapphire plasma tube compared to a quartz plasma tube) does result in increased active nitrogen, while the amount of active oxygen remains substantially unchanged and the corresponding ratio of active nitrogen to active oxygen being increased. FIG. 7 furthermore illustrates an optimized configuration for the nitrous oxide plasma, comprised of optimized microwave power, temperature, and plasma tube composition, which is shown to substantially reduce the silicon oxidation.

As shown, relative to plasma formed from the standard oxygen and forming gas composition, all of the plasmas formed of nitrous oxide exhibited lower oxidation as a function of resist removed. In addition, lowering the temperature and power setting resulted in lower oxidation and an increased ashing rate. Moreover, the plasma formed from nitrous oxide exhibited much faster ashing rate compared to the control plasma of forming gas.

### Example 6

In this example, optical emission spectroscopy was used to analyze the plasma formed from nitrous oxide relative to a standard plasma process formed from 90% oxygen gas and 10% forming gas (3% H₂/97% N₂). The plasmas from each gas were generated in the RPS320 with 3500 W and a total gas flow of 7 slm. The optical emission of the plasma was collected with an Ocean Optics optical emission spectrometer through a view port on the process chamber at wafer level.

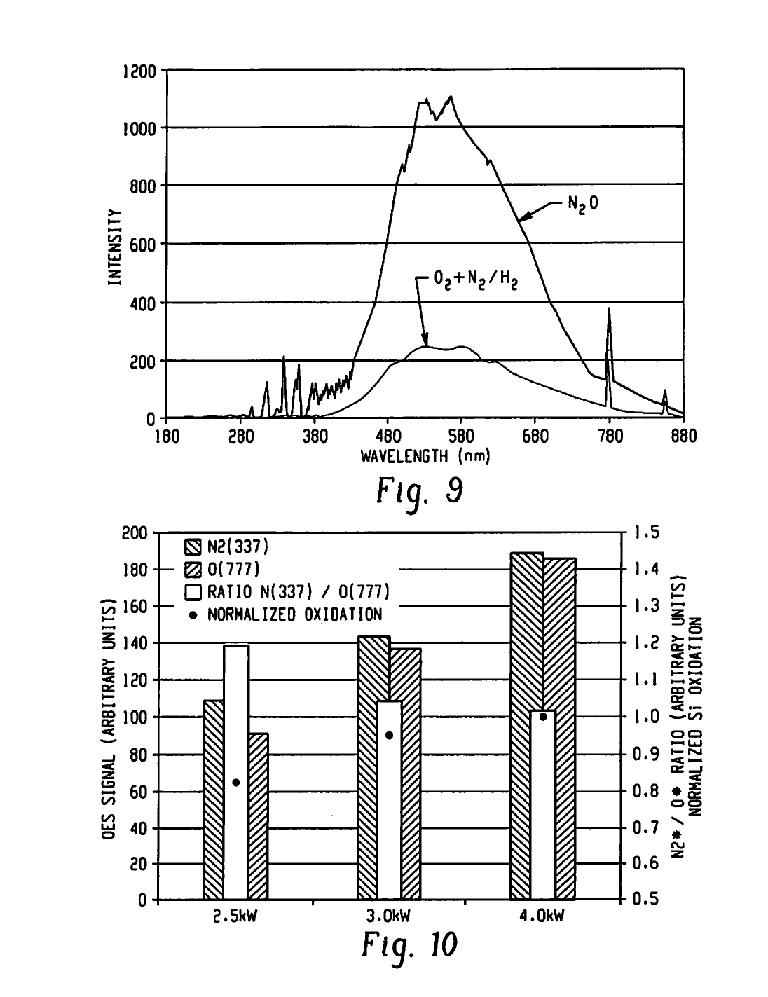

FIG. 9 graphically illustrates wavelength as a function of intensity. Noteworthy are the emission signals between about 300 and 380 nm that correspond to N₂* active species that are generated in the plasma formed from nitrous oxide. In contrast, no discernible amounts of N₂* were observed at these wavelengths for the standard plasma process. As such, the ratio of active oxygen to active nitrogen (O*:N₂*) is significantly higher in the standard plasma process than the nitrous oxide process. While not wanting to be bound by theory, the N₂* is believed to contribute to the lower oxidation in the nitrous oxide process by an apparent nitridation of the silicon-silicon oxide interface as depicted graphically in FIG. 21, but also appears to contribute to a lower ashing rate as well. In addition to this observation, the figure graphically shows that the nitrous oxide based process produced significantly more NO.

### Example 7

In this example, optical emission spectroscopy was used to measure the ratio of active nitrogen species to active oxygen species as a function of microwave plasma for plasmas formed from nitrous oxide gas. Using the RapidStrip320 plasma ashing tool, the plasma chemistry was formed by flowing nitrous oxide gas at 7 standard liters per minute (slm) into the plasma ashing tool at a pressure of 1.0 Torr, a temperature of 240° C. As shown in FIG. 10, the ratio increased as a function of lowering the microwave power, wherein a ratio of 1.2 was observed at the lowest evaluated setting of 2.5 kW. Also shown is the relative amount of silicon surface oxidation for the tested nitrous oxide plasma conditions, illustrating good correlation of the amount of silicon oxidation to the ratio of active plasma nitrogen and active oxygen species.

### Example 8

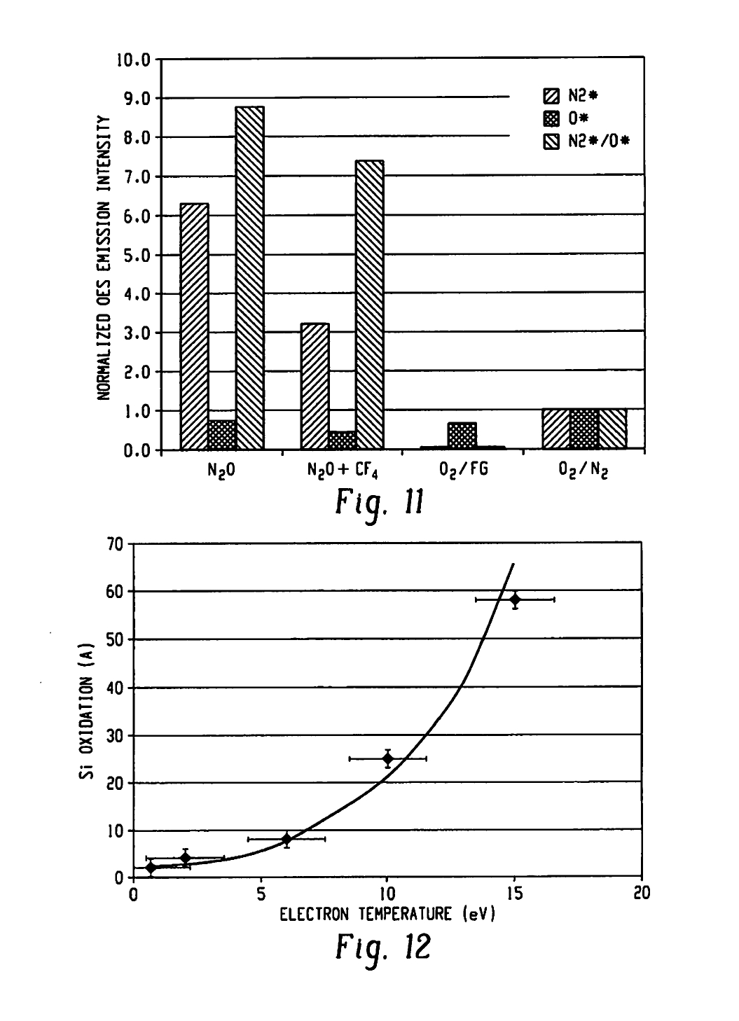

In this example, optical emission spectroscopy was used to measure the ratio of active nitrogen to active oxygen species for plasmas formed from (i) nitrous oxide gas, (ii) nitrous oxide gas with a CF₄ additive, (iii) a mixture of 90% oxygen gas and 10% forming gas (3% H₂/97% N₂), and (iv) a mixture of 90% oxygen gas and 10% nitrogen gas. For the purpose of illustration, the amounts of measured active oxygen and active nitrogen shown in FIG. 11 for the different plasmas were normalized to reflect a value of one for the O₂+N₂ plasma. The corresponding ratio of active nitrogen to active oxygen are substantially higher for the plasmas formed with the nitrous oxide gas mixtures and lower for the plasma formed from the gas mixture of O₂+FG gas mixture, which is well correlated with the earlier reported amounts of silicon oxidation. It is noteworthy to mention that the amounts of active oxygen are relatively similar for all four evaluated plasmas, and that there are significant differences in the amounts of active plasma nitrogen.

### Example 9

In this example, FIG. 12 graphically illustrates the amount of silicon oxidation as a function of the electron temperature for oxidizing plasma. Plasmas formed from 90% oxygen gas and 10% forming gas showed that silicon oxidation increases exponentially as the electron temperature of the plasma increases. Low silicon oxidation requires maintaining a low electron temperature below about 5.0 electron volts.

### Example 10

In this example, the oxide growth of silicon substrates and the ashing rates of photoresist were measured for various plasmas. The plasmas were formed with different gas mixtures using a Rapidstrip320 plasma asher at a power setting of 3500 W, a gas flow of 7 slm, and a temperature of 245° C. The gas mixtures included a.) O₂ and forming gas (3% hydrogen/nitrogen); b.) N₂O; c.) N₂O+0.3% CF₄; d.) NH₃ and O₂; e.) forming gas (3% hydrogen/nitrogen)+10% N₂O; and f.) He—H₂+10% N₂O. Prior to photoresist removal the silicon substrates had the following 4 implants: i) an amorphization implant; ii) a carbon implant; iii) a halo implant; and iv) an extension implant +.

Top down scanning electron micrographs of the substrates after ion implantation, photoresist ashing, and a wet cleaning step that includes a conventional ammonium hydroxide-hydrogen peroxide mixture (APM)/sulfuric peroxide mixture (SPM). The APM cleaning step included exposing the substrate to a NH₄OH:H₂O₂:H₂O mixture (ammonium hydroxide-hydrogen Peroxide Mixture,) also known as SC1 (Standard Clean 1) or RCA 1. The SPM method, also referred to as a “piranha clean”, included exposing the substrate with H₂SO₄:H₂O₂ solution at 100° C.-130° C. The substrates were then rinsed with distilled water and dried. As shown, residues were evident in all micrographs with the exception of substrates processed with plasmas formed from the following gas mixtures: c.) N₂O+CF₄ and d.) NH₃+O₂.

Table 2 below provides oxide growth and ashing rate results for the various plasmas. The single pass oxide growth results represents oxide growth measurement after processing the wafer a single time with the corresponding plasma chemistry provided in Table 2. Each wafer and plasma chemistry conditions were substantially identical, thereby showing relative effectiveness amongst the different plasma chemistries. The twenty pass oxide growth rate represents oxide growth measurement after processing the wafer with the plasma chemistry for a cycle 20 times. It is believed the twenty pass oxide growth measurements substantially reduce measurement errors.

TABLE 2

| | OXIDE GROWTH | ASHING RATE |
|---|---|---|
| | (Σ/pass; 20 passes, \acute{Å}) | (μm/min) |
| HeH₂ + 10% N₂O | — | 2.5 |
| HeH₂ + 30% N₂O | — | 2.3 |
| NH₃ + 10% O₂ | 0.43 | 1.1 |
| NH₃ + 30% O₂ | 0.83 | 2.0 |
| NH₃ + 10% FG | | 0.9 |
| N₂O | 0.54 | 4.0 |
| O₂/FG | 1.15 | 7.8 |
| N₂O + CF₄ | 1.95 | 3.0 |

As can be seen from the 20 pass oxide growth measurements, plasma formed form a gas mixture of N₂O+CF₄ had relatively high silicon substrate damage compared to the other plasma chemistries as evidenced by the amount of oxide growth. In contrast, the plasmas formed from a gas mixture including NH₃+O₂ exhibited minimal silicon oxidation (0.43Å/pass for the 10% O₂ mixture), which relates to an equivalent silicon loss of 0.19 Å/pass, well below the 0.3 angstroms threshold for the 32 nm generation as set by ITRS. During the oxidation process, it was assumed that for every Ångstrom of silicon consumed during oxidation is converted into 2.2 Å of silicon oxide. Thus, the oxide growth measurement of 0.43Å indicates that 0.19 Å of silicon was converted to silicon oxide (0.19 Å×2.2 Å=0.43 Å). Changing the ratio as provided by the NH₃+30% O₂ gas mixture increased the resist removal rate but also increased the amount of silicon damage. A 90% NH₃—FG mix has even lower silicon substrate oxidation than the 90% NH₃—O₂ mix but also exhibited a lower ashing rate, which would translate to reduced throughput.

### Example 11

In this example, several plasma ashing chemistries for high dose implantation strip (HDIS) were evaluated for silicon loss, TiN oxidiation, ashing rate, qualitative residue removal effectiveness, and implant species dopant retention.

Silicon loss was measured by exposing silicon substrates to the different plasma chemistries in a Rapidstrip320 plasma ashing tool at temperatures between 245 and 275° C., pressures between 1 and 2 Torr, and microwave powers between 3 and 4 kW. Thickness was measured before and after processing. For TiN oxidiation evaluation, a substrate including a TiN coating was exposed to the different plasma chemistries. Metals oxidation was measured by comparing sheet resistance (Rs) before and after plasma processing. Residue removal was measured qualitatively. Secondary ion mass spectroscopy (SIMS) analysis was performed to determine the dopant profile.

TABLE 3

| | | Si | Metals | | | As | B |
|---|---|---|---|---|---|---|---|
| | | Loss | Oxidation | Ashing | | Dopant | Dopant |
| | Ashing | (A/per | TiN ΔRs | Rate | Residue | Loss | Loss |
| Application | Chemistry | pass) | (%) | (μm/min) | Removal | (%) | (%) |
| Critical | N₂O | 0.24 | 47 | 4.00 | Excellent | −5.3 | −3 |
| HDIS | FG | 0.20 | −10 | 1.00 | Poor | −2 | −7 |
| | 90% NH₃ | 0.19 | 0 | 1.1 | Excellent | — | — |
| | and O₂ | | | | | | |
| | 70% NH₃ | 0.37 | 2 | 2.00 | Excellent | — | — |
| | and O₂ | | | | | | |
| | 90% NH₃ | ~0.2 | ~0 | 0.9 | Excellent | — | — |
| | and FG | | | | | | |
| | O₂ and | 0.52 | 45 | 7.80 | Good | 2.5 | 13 |
| | FG | | | | | | |

The NH₃/O₂ approach provided the lowest silicon loss, minimal metals (Ti) oxidation, and excellent photoresist and residue removal properties, thereby providing effective plasma chemistry for post high dose ion implantation stripping applications.

### Example 12

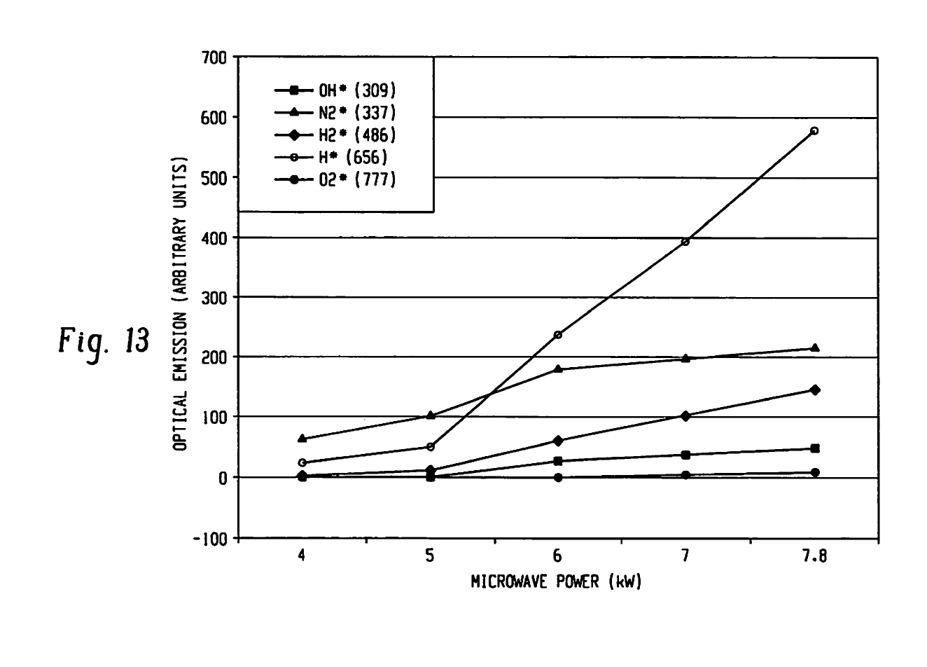

In this example, various active species were monitored by optical emission spectroscopy for plasmas generated at different power settings from a gas mixture of 90% NH₃ and 10% O₂. The plasmas were formed using a Rapidstrip320 plasma asher at a power setting of 4000 W or 7800 W, a total gas flow of 5 slm, a pressure of 1 Torr, a chuck temperature of 275° C., and a chamber wall temperature of 140° C. FIG. 13 graphically illustrates emission intensities at the different power settings for OH* at 309 nm, N₂* at 337 nm, O₂* at 358 nm, H₂* at 486 nm, H* at 656 nm, and O* at 777 nm. As shown, increasing the power to greater than 5000 W significantly increased the emission of active hydrogen (H*) and (H₂*). In addition, an increase in the emission of active N₂* was observed. Notably absent from the spectra are any significant emission intensities associated with atomic oxygen (O*) although it is apparent that some of the oxygen within the gas mixture reacted with active hydrogen to form active OH*. The foregoing data clearly suggests that the power setting can be used to tune the amount of active hydrogen when plasma is generated using NH₃ gases and mixtures thereof, which can be used to set the desired ashing rate.

### Example 13

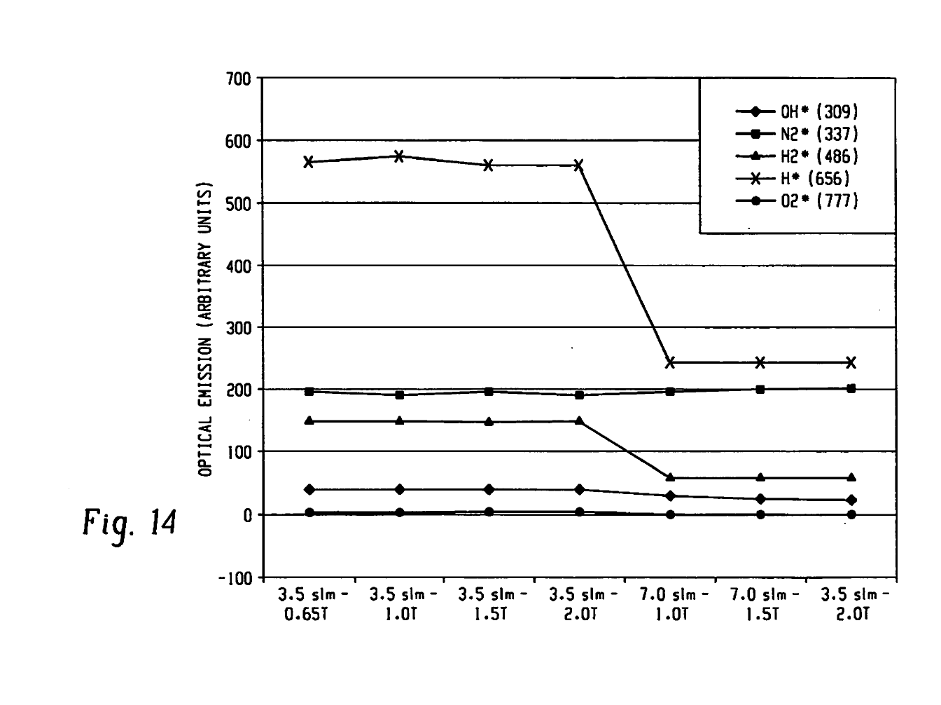

In this example, the emission intensities of various active species generated from a plasma of a gas mixture of NH₃/10% O₂ was monitored as a function of total gas flow and pressure by optical emission spectroscopy. The plasmas were formed using an Integra ES plasma asher at a power setting of 7000 W, a total gas flow of 3.5 slm or 7 slm, a pressure of 0.65, 1.0, 1.5, or 2.0 Torr, a chuck temperature of 275° C., FIG. 14 graphically illustrates emission intensities at the different pressure and total gas flow settings for OH* at 309 nm, N₂* at 337 nm, O₂* at 358 nm, H₂* at 486 nm, H* at 656 nm, and O* at 777 nm. As shown, pressure had minimal or no effect on the formation of the various active species. However, active hydrogen (H*) and (H2*) exhibited a strong dependence on total gas flow rate. A significantly higher amount of active hydrogen (H*) and (H2*) was generated at the lower total gas flow rate relative to the higher total gas flow rate. In contrast, active nitrogen (N₂*) and active oxygen (O*) exhibited no appreciable response to pressure or flow rate.

### Example 14

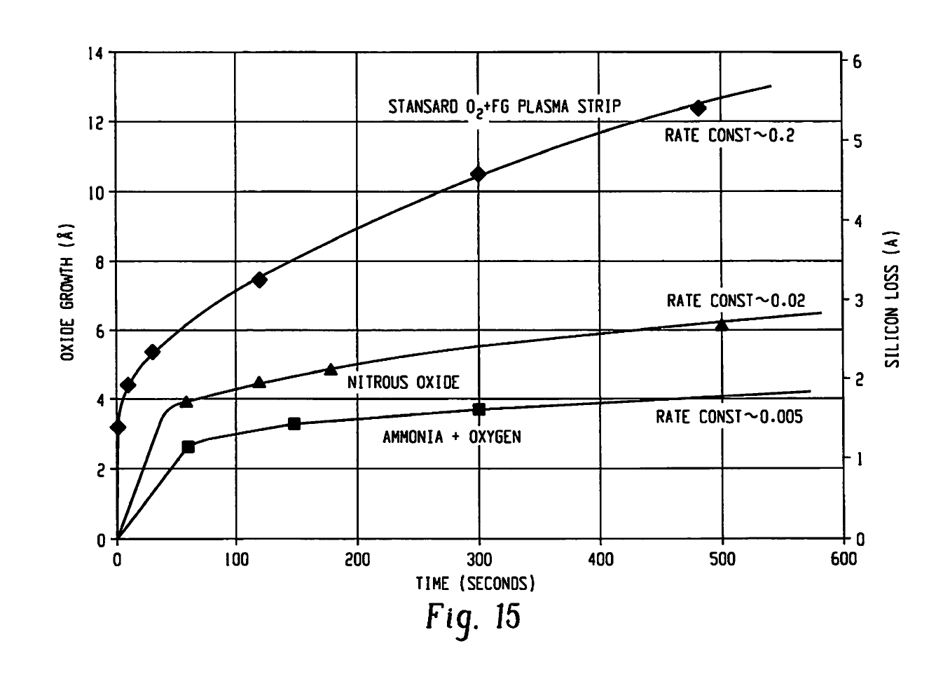

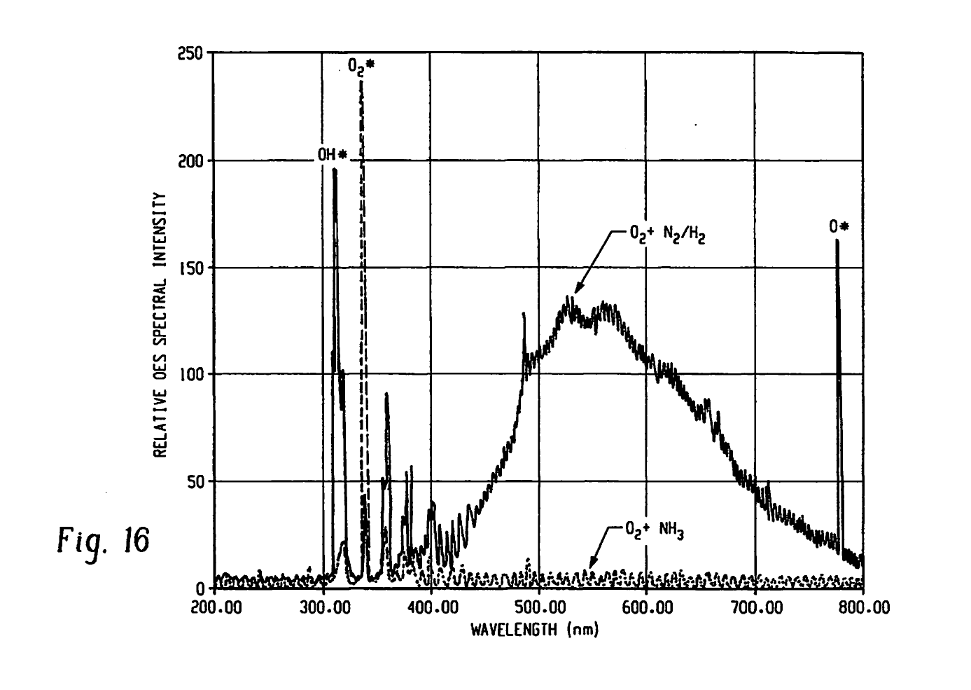

In this example, the effect of the controlled oxygen diffusion process is illustrated. FIG. 15 shows an optimized configuration for plasma generated from N₂O gas and an optimized configuration for a plasma generated from a gas mixture of NH₃/O₂, both comprised of optimized microwave power density>100 W/cm3, operating at 270° C. The Optical Emission Spectra shown in FIG. 16 shows how the addition of the NH₃ scavenging gas has completely removed all measureable atomic oxygen. Both of these plasma configurations are shown to substantially reduce silicon oxidation, because in the NH₃ case, the gas scavenging has effectively removed all atomic oxygen, and in the N₂O case, has enhanced the molecular to atomic ratio and has provided for effective nitridation of the surface oxide. Whereas the third configuration, that illustrating the greatest amount of oxide growth and silicon loss, represents a standard O₂ and forming gas plasma strip that has not been optimized to reduce the amount of fast diffusing species therein. The nitrous oxide and ammonia/oxygen plasmas, having reduced the parabolic growth rate sufficiently such that the resultant silicon oxidation is only about one monolayer.

### Example 15

In this example, optical emission spectroscopy was used to analyze the plasma formed from ammonia and oxygen using the controlled oxygen diffusion process described herein relative to a standard plasma process formed from 90% oxygen gas and 10% forming gas (3% H₂/97% N₂). The plasmas from each gas were generated in the RPS320. The optical emission spectra of the plasma was collected with an Ocean Optics optical emission spectrometer through a view port in the process chamber at wafer level.

FIG. 16 graphically illustrates wavelength as a function of intensity. Noteworthy are the emission signals between about 300 and 400 nm that correspond to OH* active species and between about 750 and 800 nm that correspond to O* active species. Both fast diffusing species are generated in the plasma formed from standard oxygen gas and forming gas processes. In contrast, no discernible amounts of O* were observed at these wavelengths for the plasma formed from NH₃/O₂, thus indicating the plasma to be free of these fast diffusing species. Also noteworthy is emission signal between about 300 and 400 nm that corresponds to the O₂* active species. As described above, an increased ratio of O₂* to O* has been found to reduce oxidation and silicon loss. As such, the ratio of molecular oxygen to atomic oxygen (O₂*:O*) is significantly higher than that of the standard plasma process.

### Example 16

In this example, the recombination coefficient of quartz and aluminum oxide are shown as a function of temperature in FIG. 17. The figure graphically illustrates the increased recombination coefficient of aluminum oxide, a scavenger of fast diffusing atomic species, compared to the standard quartz material. In general most materials experience an increase in atomic oxygen recombination as the temperature rises. As can be seen in FIG. 17, as the temperature increases to 300 C or higher the recombination coefficient increases more than 5-fold. To achieve more effective atomic recombination, the recombination surfaces should be heated either directly or indirectly to a temperature of 300° C. or higher.

### Example 17

In this example, the concentration of O₂* and O* in the plasma formed from ammonia and oxygen using the controlled oxygen diffusion process described herein was measured as a function of plasma sources power density. FIG. 18 graphically illustrates that increasing the areal power density beyond 100 W/cm³ is effective in increasing the concentration of O₂*. Without being bound by theory, and as described above, it is believed an increased ratio of neutral and excited state molecular species, such as O₂* compared to atomic species, such as O* or O, will result in an overall improved ashing process, including less silicon oxidation. As such, optimizing the power density along with the controlled oxygen diffusion plasma formation and the optional use of scavenging gases or materials are all effective in substantially eliminating the fast diffusing species in the plasma and reducing oxide growth and silicon loss.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the embodiments of the invention belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

While embodiments of the invention have been described with reference to exemplary embodiments, it will be understood by those skilled in the art that various changes can be made and equivalents can be substituted for elements thereof without departing from the scope of the embodiments of the invention. In addition, many modifications can be made to adapt a particular situation or material to the teachings of embodiments of the invention without departing from the essential scope thereof. Therefore, it is intended that the embodiments of the invention not be limited to the particular embodiment disclosed as the best mode contemplated for carrying out this invention, but that the embodiments of the invention will include all embodiments falling within the scope of the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A plasma ashing process for removing photoresist, polymers and/or residues from a substrate, the process comprising:
placing the substrate including the photoresist, polymers, and/or residues into a reaction chamber;
generating a plasma from a gas mixture comprising oxygen gas (0₂) and/or an oxygen containing gas;
suppressing and/or reducing fast diffusing species in the plasma by adding an atomic oxygen scavenging gas to the gas mixture; and
exposing the substrate to the plasma to selectively remove the photoresist, polymers, and/or residues from the substrate, wherein the plasma is substantially free from fast diffusing species.

2. The plasma ashing process of claim 1, wherein the fast diffusing species have a parabolic rate constant at 270 degrees Celsius of equal to or greater than about 0.02 Angstroms squared per second.

3. The plasma ashing process of claim 1, wherein the fast diffusing species comprise O*, O, O⁺, O⁻, H*, or a combination comprising at least one of the foregoing.

4. The plasma ashing process of claim 1, wherein suppressing and/or reducing fast diffusing species in the plasma further comprises contacting the fast diffusing species with a surface comprising a scavenging material.

5. The plasma ashing process of claim 4, further comprising heating the scavenging material to further suppress and/or reduce the fast diffusing species.

6. The plasma ashing process of claim 5, wherein heating the surface is at a temperature equal to or greater than about 200 degrees Celsius.

7. The plasma ashing process of claim 5, wherein the scavenging material has a recombination coefficient of equal to or greater than 5×10⁻⁴.

8. The plasma ashing process of claim 5, wherein the scavenging material comprises silicon dioxide, aluminum, aluminum oxide, nickel, nickel alloy, platinum, platinum alloy, titanium, titanium oxide, silver, silver alloy, tungsten, tungsten oxide, tungsten alloy, or a combination comprising at least one of the foregoing materials.

9. The plasma ashing process of claim 1, wherein the atomic oxygen scavenging gas comprises NH₃, CO, NO, or CₓH_{y}.

10. The plasma ashing process of claim 1, wherein the atomic oxygen scavenging gas comprises NH₃, and wherein the gas mixture comprises 90% NH₃ and 10% O₂.

11. The plasma ashing process of claim 9, wherein the atomic oxygen scavenging gas constitutes a sufficient portion of the gas mixture to reduce an atomic oxygen content by a factor of 4 or more.

12. The plasma ashing process of claim 11, wherein the gas mixture further comprises a forming gas mixture consisting of hydrogen gas (H₂) and nitrogen gas (N₂).

13. The plasma ashing process of claim 1, wherein the gas mixture further comprises N₂ or N₂O, wherein the plasma has a ratio of active nitrogen to active oxygen that is larger than a ratio of active nitrogen to active oxygen obtainable from a plasma formed of any oxygen gas and nitrogen gas mixture.

14. The plasma ashing process of claim 1, wherein the process includes varying a power density applied to the gas mixture.

15. The plasma ashing process of claim 14, wherein the plasma generating step comprises an excitation at a power density of at least about 75 watts per centimeter cubed.

16. The plasma ashing process of claim 13, wherein the excitation is generated by a microwave or RF power source.

17. A process for ashing organic matter from a substrate, comprising:
generating a plasma from a gas mixture comprising 0₂ or oxygen containing gas, wherein the plasma is substantially free from fast diffusing species;
combining the plasma with an atomic oxygen scavenging gas;
exposing the substrate having the organic matter thereon to the plasma; and
selectively removing the organic matter from the substrate.

18. The process of claim 17, wherein the scavenging gas reduces an atomic oxygen content in the plasma by a factor of at least about 4.

19. The process of claim 18, wherein the scavenging gas comprises NH₃, CO, C0₂, CₓH_{y} where x is an integer from 1 to 4, and y is an integer from 1 to 8, or a combination comprising at least one of the foregoing.

20. The process of claim 19, wherein a volumetric ratio of the scavenging gas to O₂ is equal to or greater than about 2 to 1.
